(19) United States
(12) Patent Application Publication
(10) Pub. No.: US 2025/0154960 A1
(43) Pub. Date: May 15, 2025

(54) ADAPTIVE RESISTOR GRID FAN CONTROL

(71) Applicant: Caterpillar Inc., Peoria, IL (US)

(72) Inventors: Jacob Dean Randall, Peoria, IL (US); Dennis Christopher Agee, Newark, TX (US)

(73) Assignee: Caterpillar Inc., Peoria, IL (US)

(21) Appl. No.: 18/507,650

(22) Filed: Nov. 13, 2023

(51) Int. Cl. F04D 27/00; B60L 7/02; H05K 7/20

(52) U.S. Cl. CPC F04D 27/004; H05K 7/20209; B60L 7/02

(57) ABSTRACT

Provided herein is a system usable with an electric drive machine. The system includes: a resistor grid electrically coupled to a motor of an electric drive machine; a fan coupled to the resistor grid, the fan operable in two or more operation modes; a control circuit comprising one or more processors and memory structured to store instructions that, when executed by the one or more processors, cause the control circuit to: determine a cooling load for the resistor grid; determine a target fan speed according to the cooling load for the resistor grid and a selected operation mode from the two or more operation modes of the fan; and provide an output corresponding to the target fan speed to the fan.

### BACKGROUND

The present disclosure relates generally to the field of a resistor grid assembly for a resistive braking system for an electric drive machine, and more particularly to improved systems and methods of operating such resistor grid assemblies.

### SUMMARY

A first aspect provided herein relates to a system including a resistor grid electrically coupled to a motor of an electric drive machine; a fan coupled to the resistor grid, the fan operable in two or more operation modes; a control circuit comprising one or more processors and memory structured to store instructions that, when executed by the one or more processors, cause the control circuit to: determine a cooling load for the resistor grid; determine a target fan speed according to the cooling load for the resistor grid and a selected operation mode from the two or more operation modes of the fan; and provide an output corresponding to the target fan speed to the fan.

In some embodiments, when operated in a first operation mode, the fan is operated at or about the target fan speed such that an amount of noise produced by the operation of the fan is minimized. In some embodiments, when operated in a second operation mode, the fan is operated at or about a maximum fan speed such that an amount of cooling produced by the operation of the fan is maximized. In some embodiments, when operated in a third operation mode, the fan is operated at or about a fan speed determined to maximize an operation lifetime of the fan. In some embodiments, the fan is operable in the two or more operation modes based on an amount, amperage, voltage, phase, or frequency of power provided to a fan motor of the fan.

In some embodiments, the control circuit selects between the two or more operation modes in response to an input from an operator of the electric drive machine. In some embodiments, the control circuit determines the target fan speed according to an elevation of the electric drive machine, an ambient air temperature, an ambient air density, a grade on which the electric drive machine is operated, the cooling load of the resistor grid, or a combination of two or more thereof.

A second aspect provided herein relates to a method of controlling an electric drive machine including: determining a cooling load for a resistor grid coupled to the electric drive machine; calculating a target fan speed according to the cooling load for the resistor grid; selecting between two or more operation modes; and controlling a fan motor such that the fan operates according to the selected operation mode at a fan speed that is at least equal to the target fan speed.

In some embodiments, when operated in a first operation mode, the fan is operated at or about the target fan speed such that an amount of noise produced by the operation of the fan is minimized. In some embodiments, when operated in a second fan mode, the fan is operated at or about a maximum fan speed such that an amount of cooling produced by the operation of the fan is maximized. In some embodiments, when operated in a third fan mode, the fan is operated at or about a fan speed determined to maximize the operation lifetime of the fan.

In some embodiments, the fan is operable in the two or more operation modes according to an amount, amperage, voltage, frequency, or phase of power provided to the fan motor. In some embodiments, selecting between the two or more fan modes is performed according to an input from an operator of the electric drive machine. In some embodiments, selecting between the two or more fan modes is performed according to a change in an elevation of the electric drive machine, a change in an ambient air temperature, a change in a grade on which the electric drive machine is operated, the cooling load of the resistor grid, or a combination of two or more thereof. In some embodiments, the method includes measuring an ambient air temperature, wherein the calculation of the target fan speed is according to the ambient air temperature. In some embodiments, the calculation of the target fan speed is according to a density of the ambient air.

A third aspect provided herein relates to an electric driving machine including: a resistor grid electrically coupled to a motor of an electric drive machine; a fan coupled to the resistor grid, the fan operable in two or more operation modes; a control circuit comprising one or more processors and memory structured to store instructions that, when executed by the one or more processors, cause the control circuit to: determine a cooling load for the resistor grid; determine a target fan speed according to the cooling load for the resistor grid and a selected operation mode from the two or more operation modes of the fan; and provide an output corresponding to a target fan speed to the fan.

In some embodiments, when operated in a first operation mode, the fan is operated at or about the target fan speed such that an amount of noise produced by the operation of the fan is minimized. In some embodiments, when operated in a second fan mode, the fan is operated at or about a maximum fan speed such that an amount of cooling produced by the operation of the fan is maximized. In some embodiments, when operated in a third fan mode, the fan is operated at or about a fan speed determined to maximize an operation lifetime of the fan.

In some embodiments, the fan is operable in the two or more operation modes based on an amount, amperage, voltage, frequency, or phase of power provided to the fan motor. In some embodiments, the control circuit selects between the two or more fan modes in response to an input from an operator of the electric drive machine. In some embodiments, the control circuit determines the target fan speed according to an elevation of the electric drive machine, an ambient air temperature, an ambient air density, a grade on which the electric drive machine is operated, the cooling load of the resistor grid, or a combination of two or more thereof.

### BRIEF DESCRIPTION OF THE DRAWINGS

FIG. 1 is a side view of a machine, according to an embodiment of the present disclosure;

FIG. 2 is a schematic diagram of an electric drive for the machine of FIG. 1, according to an embodiment.

FIG. 3 is a perspective view of an exemplary modular resistor grid system, according to an embodiment.

FIG. 4 is an exploded view of the modular resistor grid system of FIG. 3A.

FIG. 5 is a perspective view of a modular resistor grid assembly, according to an embodiment.

FIG. 6 is perspective view of a modular resistor grid of the modular resistor grid assembly of FIG. 5, according to an embodiment.

FIG. 7 is a perspective view of a resistor element, according to an embodiment.

FIG. 8 is a schematic of a resistor grid control system, according to an embodiment.

FIG. 9 is a schematic of a method of operating a resistor grid system, according to an embodiment.

### DETAILED DESCRIPTION

Before turning to the figures, which illustrate certain embodiments in detail, it should be understood that the present disclosure is not limited to the details or methodology set forth in the description or illustrated in the figures. It should also be understood that the terminology used herein is for the purpose of description only and should not be regarded as limiting.

### Electric Drive Machine

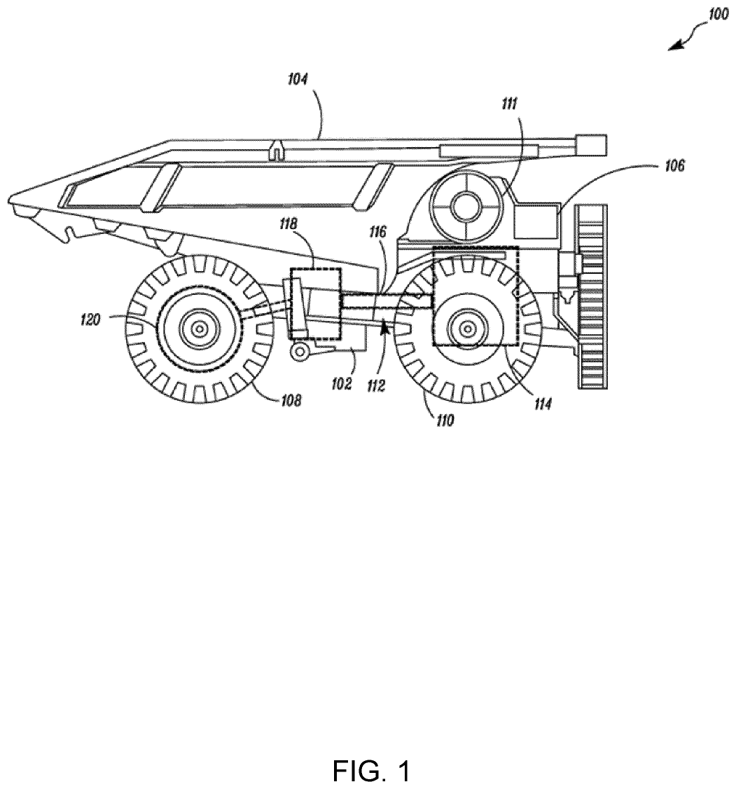

A machine 100 in which disclosed embodiments may be implemented is schematically illustrated in FIG. 1. The machine 100 may be generically described as any machine having an electric drive which may be connected to one or more drive wheels. The machine 100 may include a vehicle such as a diesel engine locomotive, a subway tram, an off-highway truck or a vehicle used in mining, construction, quarrying, and other applications. However, it will be apparent, any other vehicle having an electric drive or an electric-only arrangement may be included in the machine 100.

For the purpose of the present disclosure, in FIG. 1, the machine 100 is illustrated as an off-highway truck. The machine 100 may include a chassis 102 to support various components of the machine 100. The machine 100 may include a dump body 104 supported on the chassis 102. The chassis 102 may further support an operator cab 106 defined as an enclosure. An operator occupying the operator cab 106 may control various functions of the machine 100 by issuing various operator commands by means of controls such as a joystick, a lever, a touch-based user interface, or the like.

The machine 100 may further include a set of drive wheels 108 to propel the machine 100. In an embodiment, a set of idle wheels 110 may also be provided to steer the machine 100 in different directions. Further, the machine 100 may also include an articulated chassis for steering. Together, the set of drive wheels 108 and the set of idle wheels 110 may act as the ground engaging members for the machine 100. As illustrated in FIG. 1, the machine 100 also includes a modular resistor grid system 111 positioned adjacent to the operator cab 106 in the machine 100. However, it may be apparent, the modular resistor grid system 111 may be positioned anywhere based on the design and the available space in the machine 100.

The machine 100 of the present disclosure may be an electric machine having an electric drive 112. The electric drive 112 may provide the electric power to drive various components in the machine 100. In an embodiment, the electric power may be generated onboard by a generator, alternator, or another power-generation device, which may be driven by an engine or any other power source. Alternatively, the electric power may not be generated onboard but supplied externally from an overhead conductor via a pantograph trolley, a battery, a series of capacitors, or the like to drive the machine 100.

In the illustrated embodiment, the electric drive 112 includes a power source 114, which may be an engine, for example, an internal combustion engine such as a diesel engine, a gasoline engine, a natural gas engine or the like. The power source 114 may provide an output torque at an output shaft 116 in the machine 100. The output shaft 116 may be connected to a generator 118, which may be a multiple-phase alternating current (AC) synchronous alternator. During operation, the output shaft 116 rotates a rotor of the generator 118 to produce electric power, for example, in the form of alternating current (AC). This generated electric power may be used to run a plurality of drive motors 120 coupled directly or via intermediate assemblies to the set of drive wheels 108. For the purpose of the present disclosure, the drive motors 120 may be variable speed, reversible AC motors.

### Electric Drive and Dynamic Breaking System

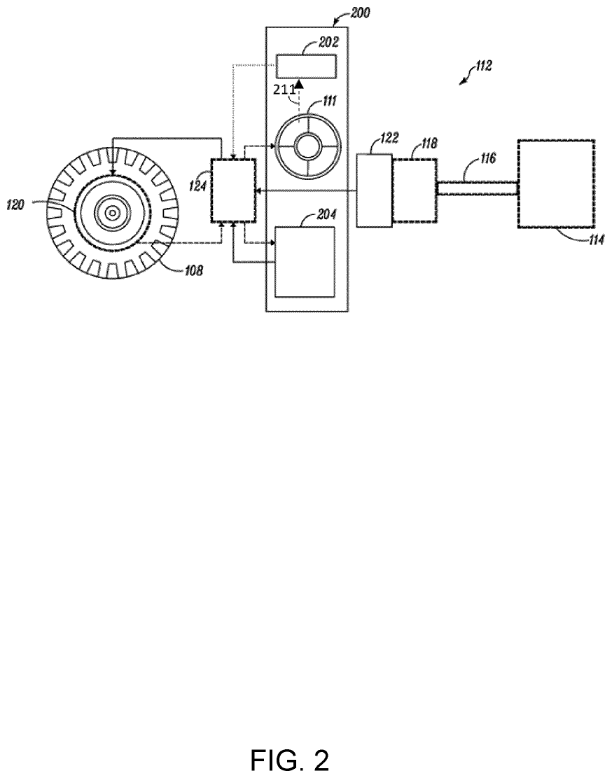

A schematic of the electric drive 112 is illustrated in FIG. 2. The electric drive 112 of the present disclosure may be a direct series drive. FIG. 2 illustrates an arrangement of various components of the electric drive 112 in the machine 100, according to an embodiment. In the schematic diagram, the flow direction of the electric power in the system is denoted by arrows. The solid-lined arrows denote the flow of the electric power when the machine 100 is being propelled. Conversely, the flow of the electric power during a braking mode of the machine 100 is denoted by dash-lined arrows in FIG. 2, while the dotted line arrow designates control line connection between components of the electric drive 112.

A person skilled in the art will understand that the generator 118 may produce electric power in the form of alternating current (AC) power. This electric power may be supplied to a rectifier 122 and converted to direct current (DC) power. The rectified DC power may be converted again to AC power by an inverter circuit 124. The inverter circuit 124 may be capable of selectively adjusting the frequency and/or pulse-width of the output, such that the drive motors 120 that are connected to an output of the inverter circuit 124 may be operated at variable speeds. In an embodiment, a plurality of inverter circuits 124 may be disposed in connection with the drive motors 120 in the machine 100.

FIG. 2 further illustrates a dynamic braking system 200 for the machine 100. The dynamic braking system 200 may be in connection with the drive motors 120 of the machine 100. Specifically, the dynamic braking system 200 may be operatively disposed in connection with the inverter circuit 124 in the machine 100. The dynamic braking system 200 may be configured to slow the propulsion of the machine 100 during braking mode as per an operator command in the machine 100.

According to the present disclosure, the dynamic braking system 200 may include a control unit 202, which may be a combination of, but not limited to, a hardware component, computing device, or other processing equipment, and memory, such as a Random Access Memory (RAM), a Read Only Memory (ROM), flash memory, a data structure, and the like. The control unit 202 may be configured to execute instructions (e.g., the processing equipment may be configured to execute the instructions stored on the data structure of the control unit 202). The control unit 202 may be configured to receive the operator command in the machine 100. Further, the control unit 202 may determine whether to put the machine 100 in the braking mode or not, based at least in part on the operator command. To initiate braking of the machine 100, the control unit 202 may generate a braking signal (illustrated by dotted line) for the inverter circuit 124. A dashed arrow represents optional signals, inputs, or data 211 that may be received by the control unit 202 from the resistor grid system 111 during operation.

The braking signal may be received by the inverter circuit 124 in the machine 100. The braking signal may carry instructions to reverse a torque polarity of the drive motors 120. This makes the drive motors 120 to act as generators, using the mechanical power in the form of rotational energy from the set of drive wheels 108 to produce electric power. This electric power may be supplied back to the electric drive 112 in the machine 100.

The dynamic braking system 200 may further be configured to provide regenerative braking in the machine 100. For this purpose, the dynamic braking system 200 may include an energy storage unit 204. The energy storage unit 204 may include a battery, a plurality of capacitors or the like disposed in connection with the drive motors 120 in the electric drive 112. As during braking mode, the drive motors 120 may produce electric power, the energy storage unit 204 may store this electric power for later use in the machine 100.

The present disclosure is applicable to many machines, for example, a large off-highway truck, such as a dump truck, which are commonly used in mines, construction sites and quarries. The machine 100 may have a high payload capability and a travel speed of a few miles per hour when fully loaded. The machine 100 may further be required to operate in a variety of environments, at a variety of altitudes, and to negotiate steep inclines in dry or wet conditions.

Typically, to halt or slow down such machines, friction-based brakes coupled to the set of drive wheels and idle wheels are used. These friction-based brakes are effective but may wear out with prolonged use. To overcome this, the dynamic braking system 200 of the machine 100 of the present disclosure may work in combination with or without these friction-based brakes. The dynamic braking system 200 may supplement these friction-based brakes in the machine 100 and thus helps in reducing the wear of such brakes.

The dynamic braking system 200 may act on the operator command to put the machine 100 in the braking mode. Specifically, the operator command may be received by the control unit 202 in the dynamic braking system 200. The control unit 202 generates the braking signal determined at least in part by the operator command. This determination or calculation may be based on various operating parameters of the machine 100, such as, the current speed, the current payload, the rate of acceleration, the desired speed and so forth.

Subsequently, the braking signal may be received by the inverter circuit 124 in the electric drive 112 of the machine 100. In the braking mode, the electric drive 112 may switch the torque polarity of the drive motors 120, which makes the drive motors 120 to act as generators. In this mode, the drive motors 120 may use the power from the set of drive wheels 108, which ultimately discharges the mechanical energy of the set of drive wheels 108 and achieves slowing or braking of the machine 100. Further, the drive motors 120, consuming the mechanical power from the set of drive wheels 108, may generate electric power in the electric drive 112.

This generated electric power may be fed to the dynamic braking system 200 in the electric drive 112. The generated electric power, which may be in the form of AC, may be fed via the inverter 124 which converts AC electric power into DC electric power. In an embodiment, with the machine 100 having regenerative braking, a part of the generated electric power may be supplied to the modular resistor grid system 111 to be dissipated as heat and the remainder of the generated electric power may be supplied to the energy storage unit 204 for later use in the machine 100.

### Modular Resistor Grid System

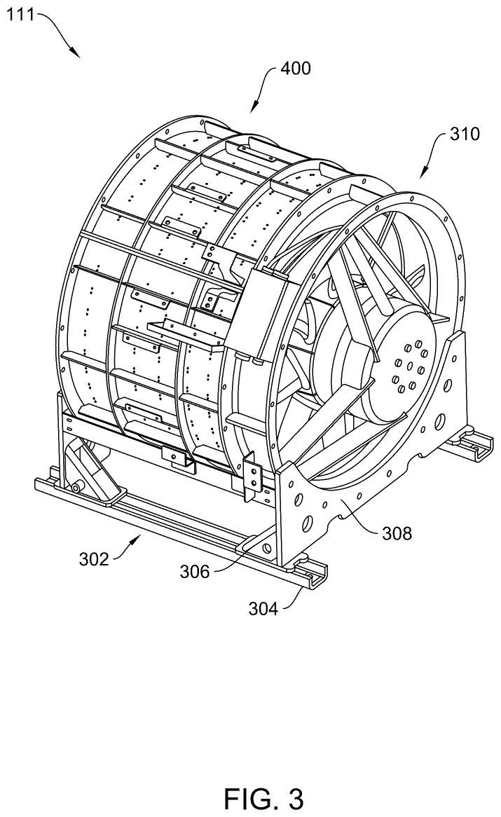

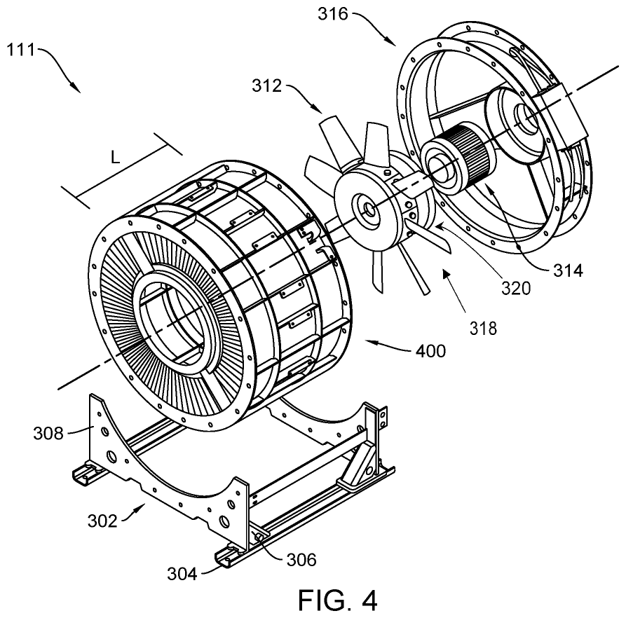

The dynamic braking system 200 may include the modular resistor grid system 111. The modular resistor grid system 111 may dissipate some or all of the generated electric power in the form of heat. FIG. 3 illustrates a perspective view of the modular resistor grid system 111, according to an aspect of the present disclosure. FIG. 4 illustrates an exploded view of the modular resistor grid system of FIG. 3.

Referring to FIGS. 3 and 4, the modular resistor grid system 111 includes a mount 302, a fan 310, and a modular resistor grid assembly 400. The mount 302 may be permanently or removably coupled to the machine 100. The mount 302 provides a support structure upon which the other components of the modular resistor grid system 111 may be secured, connected, and/or coupled to the dynamic braking system 200 of the machine 100. The mount 302 may include a frame 304 and one or more brackets 306. The frame 304 may include rigid supporting members such as bars, rails, posts, tracks, or other suitable elements to affix the components of the modular resistor grid system 111 to the machine 100. The brackets 306 may be selectively moveable brackets 306 such that one or more brackets 306 can be fastened to a first position along the frame 304, loosened, allowed to slide along the length of the frame 304 to a second position, then tightened to secure the bracket 306 in the second position. The brackets 306 may also include a mounting feature 308 configured to align or abut with the components of the modular resistor grid system 111 such that the components may be fastened together by bolts, welds, or other suitable fasteners. For example, in FIGS. 3 and 4, moveable brackets 306 are coupled to mounting features 308 that are shaped to fit the cylindrical profile of the modular resistor grid system 111, according to an aspect of the present disclosure. In this way, multiple modular resistor grid assemblies 400 of varying axial length L may be coupled to the mount 302 by sliding and securing the moveable brackets 306 as needed along the frame 304.

The modular resistor grid system 111 also includes a fan 310. In some embodiments, the fan 310 is configured to blow cooling air through the modular resistor grid assembly 400 in order to dissipate heat, for example, during a resistive braking mode of the machine 100. The fan 310 may include a blade assembly 312 configured to direct air towards or through the modular resistor grid assembly 400 as the blade assembly 312 rotates. The fan blade assembly 312 includes one or more blades 318 coupled to a support structure 320. The support structure may be a cylindrical sleeve or ring, as illustrated in FIG. 4, or may be structure known in the art for supporting fan blades. The one or more blades 318 of the fan blade assembly 312 are configured to push air when the blade assembly is rotated. A power source 314 (e.g., a motor, battery, etc.) may power the fan 310, and a hub assembly 316 may direct air towards the modular resistor grid assembly 400 and/or encase and protect the components of the fan 310. In some embodiments, the blade assembly 312 is caused to rotate by the power source 314. In other embodiments, the blade assembly 312 is coupled to a rotor (not shown) that is rotated by the power source 314, which then causes the blade assembly to rotate.

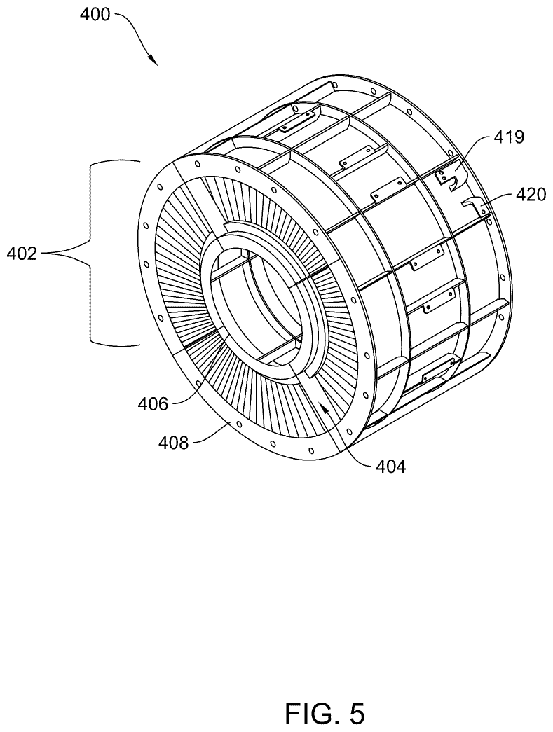

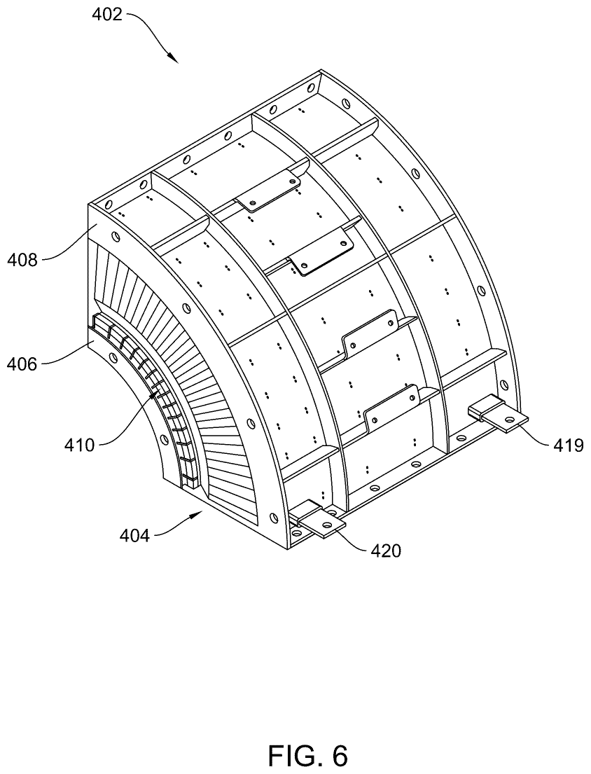

The modular resistor grid system 111 includes a modular resistor grid assembly 400. The modular resistor grid assembly 400 facilitates resistive braking by receiving and dissipating power from the machine 100 in the form of heat. In some embodiments, the modular resistor grid assembly 400 may be formed by as a single unit or may be formed from a single modular resistor grid. In other embodiments, the modular resistor grid assembly 400 may be formed by coupling together multiple modular resistor grids 402 (See, e.g., FIGS. 5 and 6 discussed below). The modular resistor grid assembly 400 includes a housing 404 which may provide support to various elements of the modular resistor grid system 111. In the illustrated example of FIGS. 3-5, the housing 404 has a cylindrical shape having an inner wall 406 and an outer wall 408. The housing 404 may be in any shape and may divided into one or more modular sections. For example, the housing 404 of the modular resistor grid assembly 400 may be formed by coupling together two or more modular resistor grids 402, each having a housing 404 encasing one or more resistor elements 410. The modular resistor grids 402 may be cylindrical, semicylindrical, quadrant-shaped, wedge-shaped, triangular, or other suitable shapes. The number of subsections of housing 404 and the number of individual modular resistor grids 402 that may be coupled together to form the modular resistor grid assembly 400 may vary depending on the space constraints in the machine 100.

For example, FIG. 5 and FIG. 6 illustrate an embodiment of the modular resistor grid assembly 400 that is divided into four quadrant-shaped modular resistor grids 402, which are assembled with each other in the machine 100. The modular resistor grid assembly 400 and the modular resistor grid 402 include at least one resistor element 410 disposed between the inner wall 406 and the outer wall 408 of the housing 404. The modular resistor grid assembly and/or the modular resistor grid 402 may include two or more resistor elements 410 (e.g., a plurality of resistor elements 410) that are closely packed in a stacked configuration abutting in an end-to-end orientation. The resistor elements 410 may be uniformly arranged in the housing 404 to maintain air spaces between each other. This uniform spacing assures an adequate flow of cooling air between the resistor elements 410 in the modular resistor grid system 111. Moreover, one or more cooling air vents may be provided in the housing 404 for circulation of cooling air in the modular resistor grid system 111.

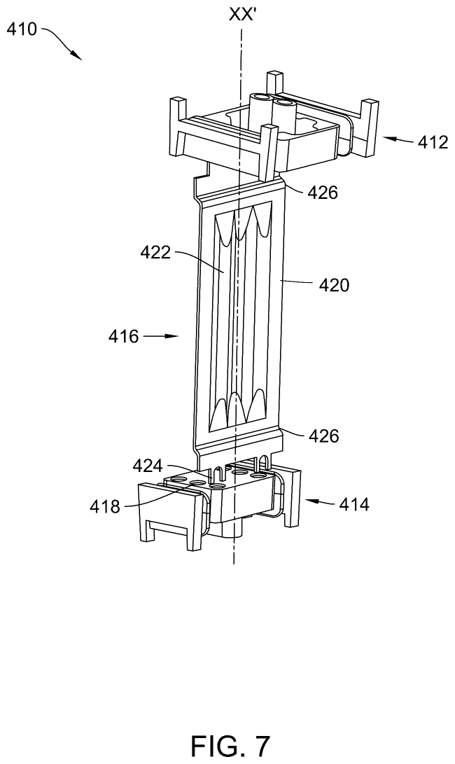

FIG. 7 illustrates an resistor element 410 according to an embodiment. The resistor element 410 includes a first insulator 412, a second insulator 414, and one or more resistor plates 416 mounted to the first insulator 412 and the second insulator 414. In the example illustrated, the resistor plate 416 is mounted between the first insulator 412 and the second insulator 414, which in turn may be affixed to the inner wall 406 and the outer wall 408 of the housing 404 of the modular resistor grid assembly 400 and/or the modular resistor grid 402. Further, the one or more resistor elements 410 may be arranged in one or more rows, substantially parallel to each other in a close face-to-face relationship forming an axial airflow path therebetween. Multiple resistor plates 416 of the resistor element 410 may be connected in series within each modular resistor grid 402 and/or the modular resistor grid assembly 400 to provide a continuous current path between an input terminal 419 and an output terminal 420 (See FIGS. 5 & 6) of the modular resistor grid 402 and/or the modular resistor grid assembly 400. For this purpose, a conducting member may be disposed in the housing 404, electrically connecting the two or more resistor plates 416 in the modular resistor grid system 111. The conducting member may be a conductive wire, a weld, etc. The resistor units 410 may be connected in a manner such that the modular resistor grid system 111 may have two current circuits, a contactor power circuit and a chopper power circuit.

As illustrated, the first insulator 412 and the second insulator 414 may be in the shape of a block made of insulating material such as silicon bonded laminated mica, ceramic, glass reinforced material, etc. However, any other material with insulating properties may be used to form the first insulator 412 and the second insulator 414. The first insulator 412 may be affixed to the outer wall 408 of the housing 404 by some fastening member, such as, nuts and bolts, screws, etc. The second insulator 414 may be similarly fastened to the inner wall 406 of the housing 404. The first insulator 412 and the second insulator 414 may each include one or more apertures 418 formed therein. Further, the apertures 418 may not be extending through the first insulator 412 or the second insulator 414 and may be configured to receive and mount the resistor plate 416 between the first insulator 412 and the second insulator 414.

The resistor plate 416 may be formed from a continuous strip of resistive material such as stainless steel. The resistor plate 416 may include a body portion 420 extending along a longitudinal direction XX′ of the resistor plate 416. In an embodiment, the resistor plate 416 may also include a series of reflexed portions 422 disposed at opposite longitudinal sides in the body portion 420 of the resistor plate 416. In some configurations, the resistor plate 416 may extend in the range of about 150 millimeters to about 200 millimeters along the longitudinal direction XX′. In a specific example, the resistor element 404 may have a length of about 160 millimeters. The resistor plate 416 may have a tip portion 424 disposed at an end 426 off the body portion 420. Alternatively, the resistor plate 416 may include two or more tip portions 424 disposed from both the ends 426. The tip portions 424 of the resistor plate 416 may be adapted to be received in the apertures 418 of the first insulator 412 and the second insulator 414. The apertures 418 may provide some clearance for movement of the tip portions 424 within. This allows for the resistor plate 416 to move in the longitudinal direction XX′ in the resistor element 410 upon thermal expansion and thermal contraction.

During a resistive braking mode, the generated electric power may pass into the modular resistor grid system 111 via the input terminal 419 and flow through the resistor plates 416 in the resistor element 410 of the modular resistor grid system 111 to be dissipated as heat. Specifically, the heat is generated by the body portion 420 of the resistor plate 416. This generated heat may be radiated to the first insulator 412 and the second insulator 414 and raise the temperature of the first insulator 412 and the second insulator 414 in the resistor element 410. The normal continuous operating temperature for the first insulator 412 and the second insulator 414 is in the range of 300 to 400 degrees Celsius, according to industry standards. For short intervals, the temperature of the first insulator 412 and the second insulator 414 may reach higher values due to surges, but if the temperature rises above a critical or maximum operating temperature for extended periods of time, the lifetime of the first insulator 412 and the second insulator 414 may be greatly reduced. Further, the mechanical stability of the resistor plates 416 may be compromised, causing the resistor plates 416 to bend and ultimately leading to rapid failure of the dynamic braking system 200.

### Adaptive Resistor Grid Fan Control

A schematic of the resistive braking system is shown in FIG. 2. With reference to FIG. 2, in operation, during a resistive braking event, a braking signal is sent to the inverter circuit 124, causing the circuit to reverse a torque polarity of drive motors 120 coupled to the inverter circuit, thereby providing braking to the vehicle and causing the drive motors to produce electrical charge. Excess electrical charge is directed to the resistor grid system 111 to be dissipated as heat.

The amount of power that the resistor grid system is able to reject is the power capacity of the system. The power capacity of the resistor grid system 111 may depend on several variables, including, but not limited to, the length of the electrical pathway provided by the resistor elements, the resistor grid materials, the duty or operating speed of the fan, convection considerations such as the geometry of the angles and faces presented by the grid elements to the crossing air flow provided by the fan operation, among other variables and factors. The resistor grid system 111 has a power capacity of about 100 kW to about 100 MW.

Specific features of the resistive braking system are shown in FIGS. 3-7. The convective cooling provided by the resistor grid fan 310 to the resistor grid greatly increases the power capacity of the resistor grid system 111. A resistor grid fan 310 operates to blow air across the resistor elements when the resistor grid is providing resistive braking, thereby transferring heat from the resistor grid elements 410. The resistor grid fan 310 operates when power is supplied to it.

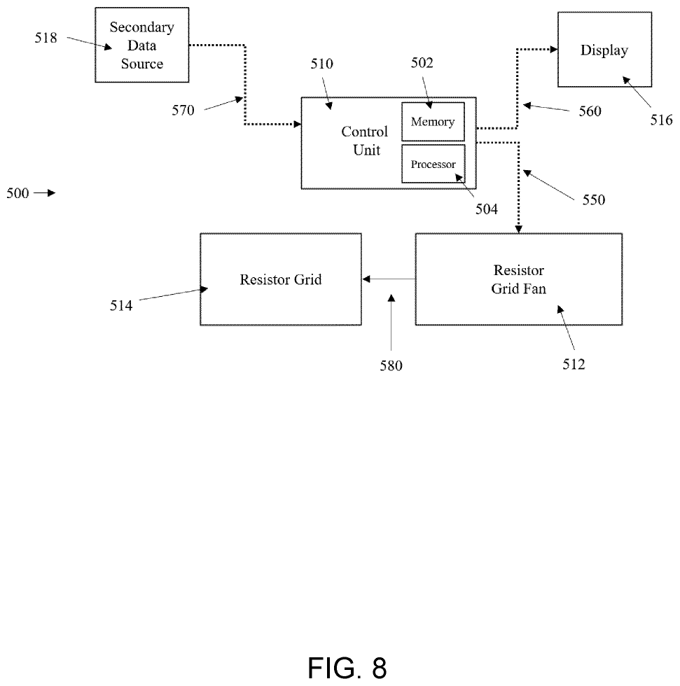

A control unit 510 may be in electronic communication with one or more fan speed sensors 520 and with the resistor grid fan 512. One embodiment of a suitable fan control circuit 500 is illustrated as a schematic diagram in FIG. 8. The control unit 510 may be configured to receive and output signals. The control unit 510 may be s able to send an operation signal 550 to the resistor grid fan 512. The operation signal may be an electronic signal setting a speed set point or an acceleration set point for the fan. During operation, the resistor grid fan provides convective cooling 580 to the resistor grid 514. The control circuit 500 may be configured to provide control of a resistive braking system of a vehicle including a power source, drive motors, and inverter, and a resistor grid system including a resistor grid fan, as previously described, while receiving data regarding the operation of the resistor grid system such as the speed of the resistor grid fan.

In an embodiment, the fan control circuit 500 includes a control unit 510, which includes one or more processors 504 and a computer memory 502. The control unit 510 may be a combination of, but not limited to, a set of instructions stored on a computer memory 502, one or more processors 502 configured to execute the set of instructions, a Random Access Memory (RAM), a Read Only Memory (ROM), flash memory, a data structure, and the like. The memory 502 stores code or executable instructions that, when executed by the one or more processors 504, sends signals 550 that control the operation of the fan 310. The signals 550 may direct a controller on the fan 512 itself to operate the fan at a designated speed, or the signals may be electrical power provided to the fan to cause the fan to operate at the designated speed.

In this way, the amperage, voltage, or frequency of power provided to the resistor grid fan is controlled by the fan control unit 510. In some embodiments, the fan control unit 510 includes circuitry to spin up the fan at a variable rate of acceleration. In some embodiments, the fan control unit 510 includes circuitry to spin up the fan at a constant rate of acceleration. In some embodiments, the fan control unit 510 includes circuitry to spin up the fan 310 to a set speed. In some embodiments, the speed of the fan 310 is dependent on the amperage of power provided. In some embodiments, the speed of the fan 310 is dependent on the voltage of power provided. In other embodiments, the speed of the fan 310 is dependent on the frequency of power provided to the fan (e.g., via a pulse-width modulated signal or some other frequency-based power signal). In some embodiments, the speed of the fan is a function of a combination of two or more of the amperage, voltage, or the frequency of the power provided to the fan 310. In some embodiments, the speed of the fan is a function of a combination of the voltage and the frequency of the power provided to the fan 310. In some embodiments, the fan may be configured to received direct current (DC) from the power supply 314 via the fan control circuit. In other embodiments, the fan may be configured to receive alternating (AC) from the power supply via the fan control circuit.

With continued reference to FIG. 8, the control unit 510 may be configured to determine, using the one or more processors and memory, a target fan speed according to the cooling duty of the resistor grid fan 512. The control unit 510 may determine the target fan speed when the fan 512 is receiving power and is actively cooling the resistor grid 514. In some embodiments, the control unit 510 may be configured to determine the target fan speed of the resistor grid fan 512 according to other available data, such as the ambient air temperature, the ambient air density, the ambient air pressure, the elevation at which the vehicle is operating, the vehicle's planned route, among other possibilities. Other variables may also be accounted for in determining the target fan speed of the resistor grid fan 512.

In some embodiments, the fan control circuit 500 may be configured to operate the fan 512 in a variable control scheme, adapting the target fan speed of the fan to operate the fan at different rotational speeds based on the amperage, voltage, or frequency of power supplied to it. The variable control scheme may include two or more operating modes, with each operating mode giving different weight to the priority of different operating parameters. As non-limiting examples, parameters that may be considered by the system include the final operating speed of the fan 512, the spin up rate of the fan, the spin down rate of the fan, the maximum operating speed of the fan, the amount of torque produced by the fan motor during operation, the strain on parts of the fan including the blades, the cooling provided by the fan to the resistor grid 514, and/or an amount of charge available in an energy storage unit, such as a battery. In some embodiments, the cooling provided by the fan 512 to the resistor grid 514 may be determined according to a pressure, temperature, or density of the ambient air in which the vehicle is operating or an elevation of the vehicle.

In some embodiments, in a first mode, the control unit 510 prioritizes maximizing the cooling provided to the resistor grid 514 by the fan 512. In such a mode, the fan 512 is controlled by the fan control unit 510 to operate at or near a maximum operating speed. In this mode, spin up rate of the fan 512 to the target operating speed may produce higher strain on the fan components when compared to other operating modes. The strain placed on the fan components while operating in this mode may be close to the maximum tolerable strain of the fan components. While operating in this mode, the control unit 510 may provide an amount of electrical charge that is close or that meets the maximum charge for which the fan is rated. This mode may be suitable for limited periods of operation in which the duty of the resistor grid 514 is high, such as when the vehicle traverses a downhill portion of a route. In addition to the active cooling provided by the fan 512, the power consumed by the fan operating at a high operating speed may act or function as a parasitic load on the vehicle, thereby further dissipating power produced by the vehicle.

In some embodiments, in a second operating mode, the control unit 510 prioritizes maximizing the operating life of the fan 512. When operating in this mode, the fan 512 is controlled by the fan control unit 510 to have a spin up and/or spin down rates that produce less strain in the fan components when compared to other operating modes. An operating mode that prioritizes the operating lifetime of the fan 512 may have a target operating speed that is lower than the maximum operating speed of the fan.

In some embodiments, in a third operating mode, the control unit 510 prioritizes minimizing an amount of noise produced by the fan 512 while still providing adequate cooling to the resistor grid 514. In some embodiments, the target operating speed may be set by the operator. The target operating speed may be a percentage of a maximum operating speed of the fan. For example, in some embodiments, the target operating speed may selected from 95%, 90%, 85%, 80%, 75%, 70%, 65%, 60%, 55%, 50%, 45%, 40%, 35%, 30%, 25%, 20%, 15%, or 10% (or any other interval/step size/percentage/ratio) of the maximum operating speed of the fan 512. In other embodiments, the target fan speed is adjusted automatically by the fan control unit 510 to operate near or at the lowest operating speed which provides sufficient cooling to the resistor grid to meet the resistor grid duty. The control unit 510 may determine the resistor grid duty according to one or more of a temperature of the resistor grid, a load on the resistor grid, an ambient air temperature, an ambient air density, an elevation of the electric drive machine, or any other variable which may be used by the control unit 510 to determine an amount of cooling to be supplied by the fan 512 to the resistor grid 514.

The preceding discussion of modes should be considered to be non-limiting. As would be recognizable by a person skilled in the art, additional modes of operation of the fan are possible accounting for the parameters discussed above. As non-limiting examples, in some embodiments, an operation mode may operate the fan 512 in such a way as to not exceed a particular strain level on a given fan part, such as the blades. In some embodiments, an operation mode may prioritize minimizing usage of battery power while still maintaining sufficient cooling of the resistor grid components. In some embodiments, a mode of operation may operate the fan 512 in such a way as to periodically reduce the buildup of dust or other fouling on the fan blades. In some embodiments, a mode of operation may operate the fan 512 in such a way as to periodically remove dust or other fouling from the resistor grid. In some embodiments, a mode of operation may operate the fan 512 in such a way as to maintain constant mass flow rate or volumetric flow rate of air across the resistor grid 514.

In some embodiments, the mode of operation of the fan may be selected in response to an input by an operator. In some embodiments, the mode of operation of the fan may be selected automatically by the fan control unit in response to one or more inputs received by the fan control unit. As non-limiting examples, the fan control unit may receive inputs such as temperature readings from the resistor grid, temperature readings of various fan components (e.g., the motor, rotor, blades, etc.), a pressure reading of the airflow produced by the fan, a measurement of noise produced by the fan operation, a density of the air, an ambient air temperature, or an elevation of the vehicle, and the fan control unit may select the operating mode according to one or more of those measurements or inputs.

The fan speed sensor may measure the speed of one or more of the fan blades 312, the speed of the support structure 320 of the fan blade assembly 310, or the speed of a rotor (not shown) of the fan 310. One skilled in the art will recognize that other portions of the fan may be suitable for determining the rotational speed of the fan. Any type of sensor known in the art suitable to determine the speed of an object may be used. As a non-limiting example, in some embodiments, the fan speed sensor 520 is a gear tooth sensor. In other embodiments, the fan speed sensor 520 is an optical sensor, a magneto-resistive sensor, or a Hall-effect sensor. While this disclosure references a single sensor, it should be understood that it is possible to combine multiple speed sensors and use the combined data provided thereby. Measuring the speed of multiple resistor grid fan locations may increase the redundancy of the data and improve data fidelity.

As discussed above, the fan control system 500 may include one or more secondary data sources 518. The secondary data sources may include, but not be limited to, remote or local databases or servers, processors, memory, and/or local or remote sensors. For example, the control unit 510 may receive a signal 570 corresponding to the temperature of the ambient air around the vehicle, the density of the ambient air around the vehicle, the elevation at which the vehicle is operating, the time of day, or information regarding the planned route of the vehicle. Even though a single source 518 is shown, it should be understood that each of these data signals could be provided by a separate sensor or other data source, such as a temperature sensor configured to measure the temperature of the ambient air around the vehicle or an altimeter configured to measure the elevation at which the vehicle is operating. It should also be understood that a single source may provide multiple data points. For example, a remote server may transmit a signal providing data on the elevation of the vehicle and the ambient air density or pressure.

The control unit 510 may be configured to provide an output signal 560 to an interface or network (not shown). Information determined by, calculated by, derived by, identified by, or otherwise present in the control unit 510 can thus be transmitted by an output signal to other devices. In some embodiments, the interface is a user interface such as a graphical display. A display may be positioned in the cab showing the target operating speed of the resistor grid fan 512, if desired. In an embodiment in which the target operating speed of the fan 512 is selected by an operator, the display may also display a recommended target operating speed for the fan. For example, the operating speed of fan required to satisfy the cooling duty for the resistor grid fan 512 may be displayed so as assist an operator in avoiding operating the fan at higher speeds than is necessary. This may extend the operating lifetime of the fan and may reduce the amount of noise produced by the fan in certain operating environments.

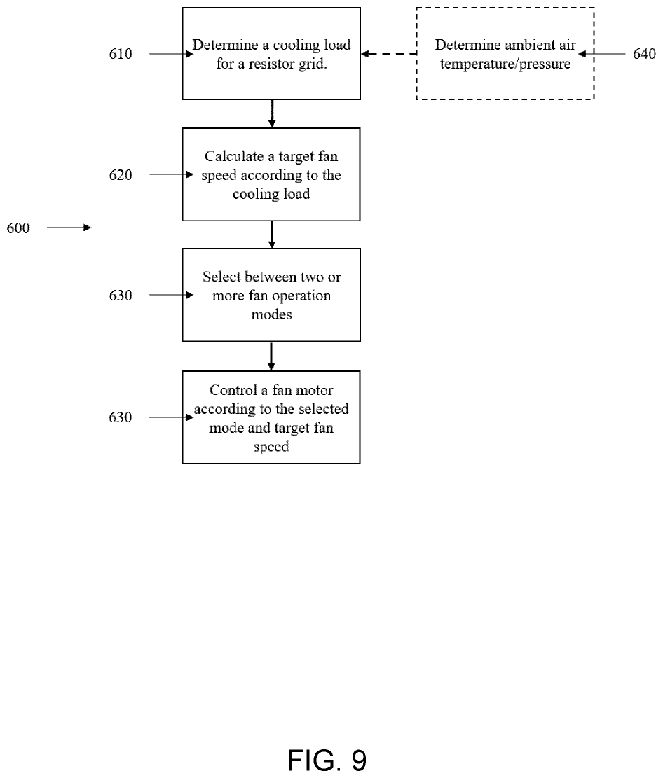

These principles can be applied to a method of operating a vehicle with a resistive braking system utilizing a fan to adaptively operate the fan. With reference to FIG. 9, a method 600 of operating such a vehicle is shown according to an embodiment. In the first step 610, one or more processors associated with a control unit on the vehicle may determine the cooling load associated with the resistor grid providing resistive braking capacity to the vehicle. The processor(s) may determine the cooling load according to an ambient air temperature, an ambient air density, an elevation of the vehicle, a capacity of the resistor grid, a temperature of a component of the resistive braking system, a maximum fan speed, a fouling factor of the resistor grid, a fouling factor of the fan, or another parameter related to the resistor grid system. In some embodiments, the processor(s) may determine the cooling load in response to a measured temperature of a change in the temperature of a component of the resistive braking system.

The processor(s) may determine the cooling load in response to an instruction, a signal, or an input, which may be provided by an operator or may be provided by an automated system. The processor(s) may determine the cooling load after a certain period of time has passed since a prior cooling load determination. As a non-limiting example, the processor(s) may determine the cooling load every 1 second, every 5 second, every 10 second, every 20 seconds, every 30 second, every 1 minute, every 2 minutes, every 5 minutes, every 10 minutes, every hour, or any fraction of time as desired. The time between determinations of the cooling load by the processor(s) may be constant, or it may vary. For example, in some embodiments, a time delay between a second and third determination of the cooling load may be shorter or longer than the delay between a first and second determination depending on a comparison of the first and second cooling loads. For example, in some embodiments, if the second cooling load is greater than the first cooling load, the time between the second and third determinations may be reduced compared to the delay between the first and second determinations. The reverse may also be true, i.e., the delay between the second and third determination may be greater than the delay between the first and second determinations if the second cooling load is lower than the first.

In a second step 620, the one or more processors may determine a target fan speed according to the cooling load for the resistor grid. The processor(s) may determine the target fan speed based on the cooling load. The processor(s) may determine the target fan speed according to one or more of an ambient air temperature, an ambient air density, an elevation of the vehicle, a capacity of the resistor grid, a temperature of a component of the resistive braking system, a maximum fan speed, a fouling factor of the resistor grid, a fouling factor of the fan, a predicted path of the vehicle, or another parameter related to the resistor grid system or vehicle. The processor(s) may retrieve data from one or more sensors, according to the cooling load. For example, the processor(s) may perform a look-up function in memory using the cooling load, to determine a target fan speed which corresponds to the cooling load. The processor(s) may compute the target fan speed as a function of the cooling load with consideration for the factors previously listed.

In step 630, an operating mode for the fan is selected from two or more operating modes. The operating mode may be selected in response to an input from an operator. The operating mode may be selected automatically in response to a change in an ambient air temperature, an ambient air density, an elevation of the vehicle, a capacity of the resistor grid, a temperature of a component of the resistive braking system, a maximum fan speed, a fouling factor of the resistor grid, a fouling factor of the fan, an elevation of the vehicle, a predicted path of the vehicle, a position of the vehicle, or another parameter related to the resistor grid system or vehicle. In some embodiments, the selection of an operating mode may default to an operating mode corresponding to an input from an operator. In some embodiments, the default operating mode corresponding to an input from an operator can be temporarily overridden by a control unit in response to one or more of the factors listed. As a non-limiting example, in some embodiments an operator may select a low-noise operating mode for the fan which can be overridden by the system should a measured temperature of the resistor grid system exceed a setpoint value.

The fan is controlled in step 640 so as to according to the selected mode and the target operating fan speed. The fan may be controlled by the control unit of the vehicle providing electrical current to the fan. In some embodiments, the fan speed is controlled by the control unit adjusting the voltage, amperage, or frequency of the electrical current, or a combination of two or more thereof. The control unit may adjust the electrical current over a period of time so as to allow the fan to spin up to the target operating speed.

The method may also include a step 650 of using the one or more processors to determine the temperature and/or pressure of the ambient air in which the vehicle is operating. Sensor may provide data to the control unit associated with the processor(s), such that this data may be accounted for when the processor(s) determine the cooling load of the resistor grid system and/or the target fan speed required to meet the cooling load.

The method may also include a step of the processor(s) rendering data on a display. In some embodiments, the target operating fan speed, the cooling duty of the resistor grid, and/or the selected operating mode of the system may also be rendered by the one or more processors on a display available to an operator of the vehicle, thereby providing additional information to the operator regarding the operating conditions of the braking systems. Alternatively or additionally, the temperature and/or the density of the ambient air may also be taken into account by this method and may be rendered by the one or more processors on the display. The display may comprise one or more of a screen, an indicator, a light, a group of lights, an LED display, an LCD display, or another display unit suitable for providing the information to an operator.

As utilized herein with respect to numerical ranges, the terms “approximately,” “about,” “substantially,” and similar terms generally mean +/−10% of the disclosed values, unless specified otherwise. As utilized herein with respect to structural features (e.g., to describe shape, size, orientation, direction, relative position, etc.), the terms “approximately,” “about,” “substantially,” and similar terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the figures. It should be noted that the orientation of various elements may differ according to other exemplary embodiments, and that such variations are intended to be encompassed by the present disclosure.

The hardware and data processing components used to implement the various processes, operations, illustrative logics, logical blocks, modules, and circuits described in connection with the embodiments disclosed herein may be implemented or performed with a general purpose single- or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit or the processor) the one or more processes described herein.

The present disclosure contemplates methods, systems, and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the various exemplary embodiments is illustrative only. Additionally, any element disclosed in one embodiment may be incorporated or utilized with any other embodiment disclosed herein.

1. A system comprising:
a resistor grid electrically coupled to a motor of an electric drive machine;
a fan coupled to the resistor grid, the fan operable in two or more operation modes;
a control circuit comprising one or more processors and memory structured to store instructions that, when executed by the one or more processors, cause the control circuit to:
determine a cooling load for the resistor grid;
select, from two or more operation modes of the fan, an operation mode in which to operate the fan;
determine a target fan speed, from a range of fan speeds, according to the cooling load and the selected operation mode; and
provide an output corresponding to the target fan speed to the fan.

2. The system of claim 1, wherein, when operated in a first operation mode, the fan is operated at or about the target fan speed such that an amount of noise produced by the operation of the fan is minimized.

3. The system of claim 1, wherein, when operated in a second operation mode, the fan is operated at or about a maximum fan speed such that an amount of cooling produced by the operation of the fan is maximized.

4. The system of claim 1, wherein, when operated in a third operation mode, the fan is operated at or about a fan speed determined to maximize an operation lifetime of the fan.

5. The system of claim 1, wherein the fan is operable in the two or more operation modes based on an amount of power provided to a fan motor of the fan.

6. The system of claim 1, wherein the control circuit selects between the two or more operation modes in response to an input from an operator of the electric drive machine.

7. The system of claim 1, wherein the control circuit determines the target fan speed according to an elevation of the electric drive machine, an ambient air temperature, an ambient air density, a grade on which the electric drive machine is operated, or a combination of two or more thereof.

8. A method of operating an electric drive machine, the method comprising:
determining a cooling load for a resistor grid coupled to a motor of the electric drive machine;
selecting, from two or more operation modes of a fan coupled to the resistor grid, an operation mode in which to operate the fan;
calculating a target fan speed, from a range of fan speeds, according to the cooling load for the resistor grid and the selected operation mode; and
controlling a fan motor such that the fan operates according to the selected operation mode at a fan speed that is at least equal to the target fan speed.

9. The method of claim 8, wherein, when operated in a first operation mode, the fan is operated at or about the target fan speed such that an amount of noise produced by the operation of the fan is minimized.

10. The method of claim 8, wherein, when operated in a second operation mode, the fan is operated at or about a maximum fan speed such that an amount of cooling produced by the operation of the fan is maximized.

11. The method of claim 8, wherein, when operated in a third operation mode, the fan is operated at or about a fan speed calculated to maximize the operation lifetime of the fan.

12. The method of claim 8, wherein the fan is operable in the two or more operation modes according to an amount of power provided to the fan motor.

13. The method of claim 8, wherein selecting between the two or more operation modes is performed according to an input from an operator of the electric drive machine.

14. The method of claim 8, wherein selecting between the two or more operation modes is performed according to a change in an elevation of the electric drive machine, a change in an ambient air temperature, a change in a grade on which the electric drive machine is operated, the cooling load of the resistor grid, or a combination of two or more thereof.

15. The method of claim 8, further comprising measuring an ambient air temperature, wherein the calculation of the target fan speed is according to the ambient air temperature.

16. The method of claim 15, wherein the calculation of the target fan speed is according to a density of the ambient air.

17. An electric drive machine comprising:
a resistor grid electrically coupled to a motor of an electric drive machine;
a fan coupled to the resistor grid, the fan operable in two or more operation modes; and
a control circuit comprising one or more processors and memory structured to store instructions that, when executed by the one or more processors, cause the control circuit to:
determine a cooling load for the resistor grid;
select, from two or more operation modes of the fan, an operation mode in which to operate the fan;
determine a target fan speed, from a range of fan speeds, according to the cooling load for the resistor grid and according to the selected operation mode; and
provide an output corresponding to a target fan speed to the fan.

18. The electric drive machine of claim 17, wherein, when operated in a first operation mode, the fan is operated at or about the target fan speed such that an amount of noise produced by the operation of the fan is minimized.

19. The electric drive machine of claim 17, wherein, when operated in a second fan mode, the fan is operated at or about a maximum fan speed such that an amount of cooling produced by the operation of the fan is maximized.

20. The electric drive machine of claim 17, wherein, when operated in a third fan mode, the fan is operated at or about a fan speed calculated to maximize an operation lifetime of the fan.

21. The electric drive machine of claim 17, wherein the fan is operable in the two or more operation modes based on an amount of power provided to the fan.

22. The electric drive machine of claim 17, wherein the control circuit selects between the two or more operation modes in response to an input from an operator of the electric drive machine.

23. The electric drive machine of claim 17, wherein the control circuit determines the target fan speed according to an elevation of the electric drive machine, an ambient air temperature, an ambient air density, a grade on which the electric drive machine is operated, the cooling load of the resistor grid, or a combination of two or more thereof.
